(19) United States
(12) Patent Application Publication
(10) Pub. No.: US 2026/0144106 A1
(43) Pub. Date: May 21, 2026

(54) SEMICONDUCTOR PACKAGE

(71) Applicant: Samsung Electronics Co., Ltd., Suwon-si (KR)

(72) Inventors: Hongjin Kim, Suwon-si (KR); Kihong Jeong, Suwon-si (KR); Dongok Kwak, Suwon-si (KR)

(21) Appl. No.: 19/227,112

(22) Filed: Jun. 3, 2025

(30) Foreign Application Priority Data
Nov. 15, 2024 (KR) 10-2024-0163265

(51) Int. Cl. H01L 23/538; H01L 23/00; H01L 25/04

(52) U.S. Cl. CPC H10W 70/65; H10W 70/611; H10W 90/00; H10W 72/01; H10W 72/9445; H10W 90/24

(57) ABSTRACT

A semiconductor package includes a package substrate including a plurality of bonding pads, including first bonding pads and second bonding pads, a lower semiconductor chip group mounted on an upper surface of the package substrate, including at least one lower semiconductor chip including lower pads connected to different types of inputs, an upper semiconductor chip group on the lower semiconductor chip group, including at least one upper semiconductor chip including upper pads connected to different types of inputs, first connection interconnection lines connecting the first bonding pads and the lower pads, and second connection interconnection lines connecting the second bonding pads and the upper pads, extending onto the first connection interconnection lines to be spaced apart from each other.

### CROSS-REFERENCE TO RELATED APPLICATION(S)

This application claims benefit of priority to Korean Patent Application No. 10-2024-0163265 filed on Nov. 15, 2024, in the Korean Intellectual Property Office, the disclosure of which is incorporated herein by reference in its entirety.

### BACKGROUND

This disclosure relates to a semiconductor package.

A semiconductor package may have a form suitable for use in electronic products of an integrated circuit chip. In general, a semiconductor package may mount a semiconductor chip on a printed circuit board and electrically connect semiconductor chips to each other using a bonding wire, bump, or inkjet-printing method. With the development of the electronic industry, various studies have been conducted to improve the reliability of semiconductor packages and reduce sizes of semiconductor packages. In particular, semiconductor packages, handling high-speed signals, may be required to have a reduced size and excellent signal quality.

### SUMMARY

An aspect of this disclosure provides a semiconductor package having improved signal quality by reducing crosstalk occurring between signal interconnection lines vertically disposed with respect to a plurality of individually driven chips.

According to an aspect of this disclosure, there is provided a semiconductor package including a package substrate including a plurality of bonding pads, the plurality of bonding pads including first bonding pads and second bonding pads, a lower semiconductor chip group mounted on an upper surface of the package substrate, the lower semiconductor chip group including at least one lower semiconductor chip including lower pads connected to different types of inputs, an upper semiconductor chip group disposed on the lower semiconductor chip group, the upper semiconductor chip group including at least one upper semiconductor chip including upper pads connected to different types of inputs, first connection interconnection lines connecting the first bonding pads and the lower pads to each other, respectively, and second connection interconnection lines connecting the second bonding pads and the upper pads to each other, respectively, the second connection interconnection lines extending onto the first connection interconnection lines to be spaced apart from each other. Each of the second connection interconnection lines may include a first linear portion passing through one of the upper pads, a second linear portion offset from the first linear portion, the second linear portion passing through one of the second bonding pads, and a bent portion connecting the first linear portion and the second linear portion to each other.

According to another aspect of this disclosure, there is provided a semiconductor package including a package substrate including a plurality of bonding pads, the plurality of bonding pads including first bonding pads and second bonding pads, a lower semiconductor chip group mounted on an upper surface of the package substrate, the lower semiconductor chip group including at least one lower semiconductor chip including lower pads connected to different types of inputs, an upper semiconductor chip group disposed on the lower semiconductor chip group, the upper semiconductor chip group including at least one upper semiconductor chip including upper pads connected to different types of inputs, first connection interconnection lines connecting the first bonding pads and the lower pads to each other, respectively, and second connection interconnection lines connecting the second bonding pads and the upper pads to each other, respectively, the second connection interconnection lines extending onto the first connection interconnection lines to be spaced apart from each other. At least a portion of each of the second connection interconnection lines may overlap one of the first connection interconnection lines in a vertical direction, and the one of the first connection interconnection lines has a different type of input from an input of each of the second connection interconnection lines overlapping the one of the first connection interconnection lines.

According to another aspect of this disclosure, there is provided a semiconductor package including a package substrate including a plurality of bonding pads, a lower semiconductor chip group mounted on an upper surface of the package substrate, the lower semiconductor chip group including at least one lower semiconductor chip including first signal pads connected to first signal inputs, an upper semiconductor chip group disposed on the lower semiconductor chip group, the upper semiconductor chip group including at least one upper semiconductor chip including second signal pads connected to second signal inputs, first connection interconnection lines connecting the bonding pads and the first signal pads to each other, respectively, and second connection interconnection lines connecting the bonding pads and the second signal pads to each other to each other, respectively. The second connection interconnection lines may be offset from the first connection interconnection lines in a vertical direction.

### BRIEF DESCRIPTION OF DRAWINGS

The above and other aspects, features, and advantages of this disclosure will be more clearly understood from the following detailed description, taken in conjunction with the accompanying drawings, in which:

FIG. 1 is a schematic block diagram of a semiconductor device according to some implementations;

FIGS. 2A and 2B are schematic perspective views and exploded perspective views of a semiconductor package according to some implementations;

FIG. 3 is a schematic plan view of a semiconductor package according to some implementations;

FIG. 4 is a cross-sectional view of FIG. 3, taken along line I-I′;

FIGS. 5 to 7 are schematic plan views of a semiconductor package according to some implementations; and

FIGS. 8A to 8E are perspective views of a method of manufacturing a semiconductor package according to some implementations.

### DETAILED DESCRIPTION

Hereinafter, preferred example implementations will be described with reference to the accompanying drawings as follows.

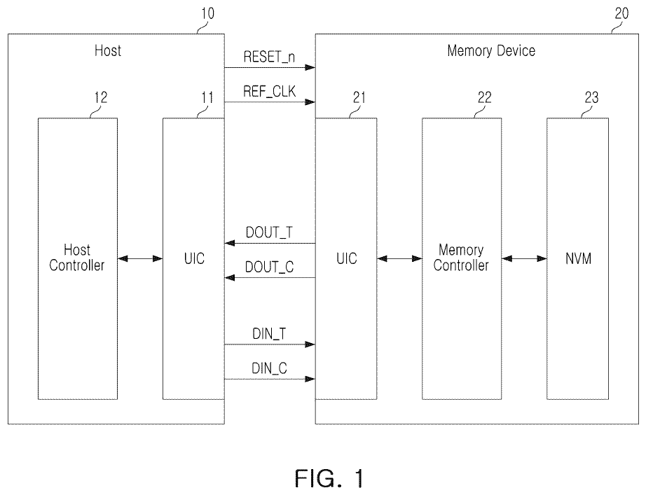

FIG. 1 is a schematic block diagram illustrating a semiconductor device according to some implementations.

A semiconductor device according to some implementations, a device, complying with the UFS standard published by the Joint Electron Device Engineering Council (JEDEC), may include a host 10 and a memory device 20.

The host 10 may include a host controller 12, an application, a host driver, a host memory, and a UFS interconnect (UIC) layer 11. The host 10 may control an overall operation of the semiconductor device, and more particularly, operations of other components included in the semiconductor device.

The memory device 20 may function as a non-volatile storage device storing data regardless of whether power is supplied, and may have relatively high storage capacity. The memory device 20 may include a UIC layer 21, a memory controller 22, a non-volatile memory 23, and the like. An input signal and an output signal may be transmitted or received between the UIC layer 11 of the host 10 and the UIC layer 21 of the memory device 20. Referring to FIG. 1, the memory controller 22 and the UIC layer 21 are illustrated separately, but this disclosure is not limited thereto, and the memory controller 22 may include the UIC layer 21.

The memory device 20 may include a memory controller 22 and a non-volatile memory 23 storing data under the control of the memory controller 22. The non-volatile memory 23 may include a plurality of memory units, and the memory unit may include a V-NAND flash memory having a 2D structure or a 3D structure but may also include other types of non-volatile memories such as PRAM and/or RRAM.

The memory device 20 may be included in the semiconductor device in a state of being physically isolated from the host 10 or may be implemented in a package the same as that of the host 10. In addition, the memory device 20 may have a form such as a solid-state device (SSD) or a memory card. The memory device 20 may be a device to which a standard protocol such as a UFS, an embedded multi-media card (eMMC), or a non-volatile memory express (NVMe) is applied, but this disclosure is not limited thereto.

The memory device 20 may include a plurality of memory groups, respectively driven by different channels receiving signals and power. Each of the memory groups may include at least one memory chip, and at least one memory chip of each memory group may be driven together by simultaneously transmitting and receiving signals and power.

A line for transmitting a reference clock REF_CLK, a line for transmitting a hardware reset signal RESET_n for the memory device 20, a pair of differential input signals DIN_T and DIN_C, and a pair of differential output signals DOUT_T and DOUT_C may be included between the host 10 and the memory device 20. Referring to FIG. 1, a pair of lines for transmitting the pair of differential input signals DIN_T and DIN_C may be included in a reception lane, and a pair of lines for transmitting the pair of differential output signals DOUT_T and DOUT_C may be included in a transmission lane.

The reception lane and the transmission lane may transmit data in a serial communication manner, and full-duplex communication between the host 10 and the memory device 20 may be performed using a structure in which the reception lane and the transmission lane are isolated from each other. That is, the memory device 20 may transmit data to the host 10 through the transmission lane even while receiving data from the host 10 through the reception lane.

VCC, VCCQ, and VCCQ2 may be input to the memory device 20 as a power voltage. VCC, a main power voltage for the memory device 20, may have a value of 2.4 V to 3.6 V. VCCQ, a power voltage for supplying a low voltage, may be mainly used for the memory controller 22, and may have a value of 1.14 V to 1.26 V. VCCQ2, a power voltage for supplying a voltage lower than VCC and higher than VCCQ, may be mainly used for an input/output interface such as MIPI M-PHY, and may have a value of 1.7 V to 1.95 V.

In some implementations, high-speed signals may be transmitted between the host 10 and the memory device 20. For example, a signal transmitted from the memory device 20 may be required to have a speed of 3 Gbps or more. When a signal is transmitted at high speed, the signal may have degraded quality even with a small error. In particular, when interconnection lines, transmitting a signal, are adjacent to each other, mutual inductance and/or capacitance may be formed between the interconnection lines, and thus crosstalk, degrading the quality of the signal, may occur.

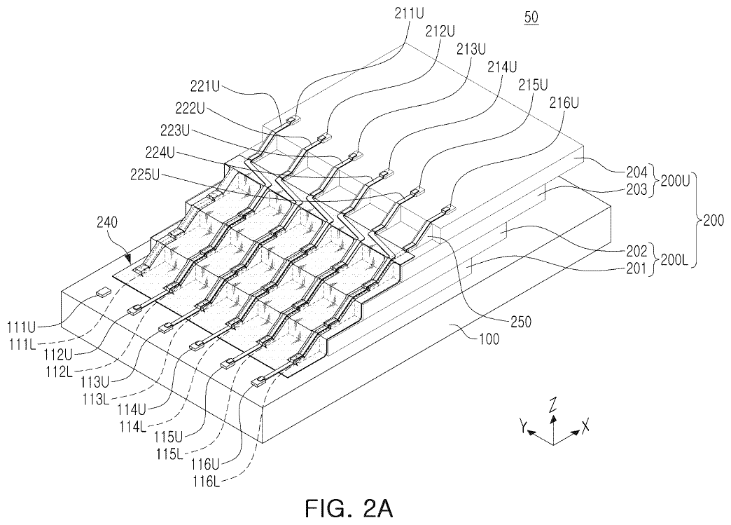

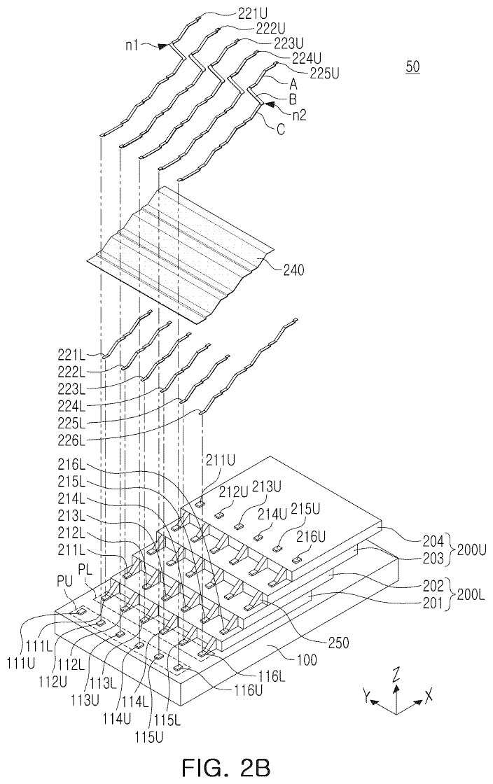

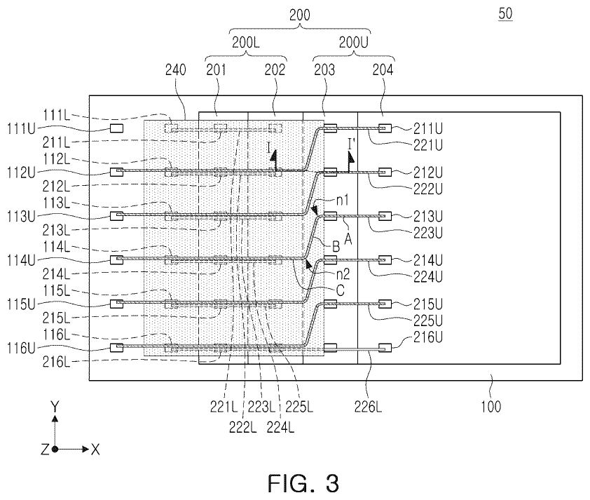

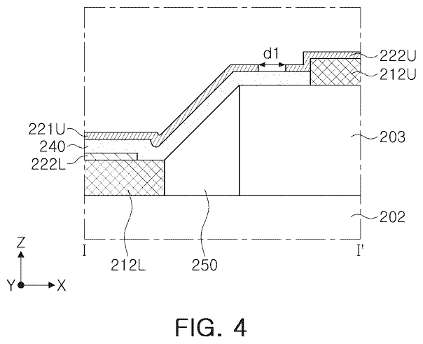

FIGS. 2A and 2B are schematic perspective views and exploded perspective views of a semiconductor package according to some implementations. FIG. 3 is a schematic plan view of a semiconductor package according to some implementations. FIG. 4 is a cross-sectional view of FIG. 3, taken along line I-I′.

In some implementations, a semiconductor package 50 may include a package substrate 100, a plurality of semiconductor chips 200, and a plurality of connection interconnection lines 221L to 226L and 221U to 225U. The plurality of semiconductor chips 200 may be mounted on an upper surface of the package substrate 100.

The package substrate 100 may be a semiconductor package substrate including a printed circuit board (PCB), a ceramic substrate, a glass substrate, a tape interconnection line substrate, and the like. For example, the package substrate 100 may be a double-sided PCB or a multilayer PCB.

The package substrate 100 may include bonding pads 111L to 116L and 111U to 116U. The bonding pads 111L to 116L and 111U to 116U may be disposed on the upper surface of the package substrate 100, and may include at least one metal or an alloy including two or more metals, among copper (Cu), aluminum (Al), nickel (Ni), silver (Ag), gold (Au), platinum (Pt), tin (Sn), lead (Pb), titanium (Ti), chromium (Cr), palladium (Pd), indium (In), and zinc (Zn). The bonding pads 111L to 116L and 111U to 116U may be electrically connected to connection bumps (not illustrated) disposed below the package substrate 100. The connection bumps may include, for example, tin (Sn) or an alloy (for example, Sn-Ag-Cu). The package substrate 100 may include a lower substrate pad on which the connection bumps are disposed, and an internal circuit connecting the lower substrate pad and the bonding pads 111L to 116L and 111U-116U to each other. The connection bumps may be electrically connected to external devices such as a module substrate, a system board, and the like.

The bonding pads 111L to 116L and 111U to 116U may include signal bonding pads 112L, 114L, 112U, and 114U and power bonding pads 111L, 113L, 115L, 111U, 113U, 115U, and 116U, spaced apart from each other. For example, the signal bonding pads 112L, 114L, 112U, and 114U may be signal pads connected to input and output terminals of data signals, and the power bonding pads 111L, 113L, 116L, 111U, 113U, 115U, and 116U may be power and ground pads connected to power terminals and ground terminals.

The bonding pads 111L to 116L and 111U to 116U may be disposed on the upper surface of the package substrate 100 in a row in a Y-direction, and may be disposed in at least two rows.

The signal and power bonding pads 111L to 116L disposed in a first row may be defined as lower bonding pads PL: 111L to 116L for providing signals and power to the lower chip groups, and the signal and power pads 111U to 116U disposed in the second row between the lower bonding pads 111L to 116L and the edge may be defined as upper bonding pads PU: 111U to 116U for providing signals and power to the upper chip groups.

The lower bonding pads 111L to 116L and the upper bonding pads 111U to 116U may provide different types of signals or power in the same column. For example, the lower bonding pads 111L to 116L in the first row may be a power pad, a signal pad, a power pad, a signal pad, a power pad, and a power pad from the left, and the upper bonding pads 111U to 116U in the second row may be a dummy pad, a power pad, a signal pad, a signal pad, a signal pad and a power pad from the left.

In this case, the lower bonding pads 111L to 116L in the first row and the upper bonding pads 111U to 116U in the second row may be shifted one column to the right to supply a signal or power.

The plurality of semiconductor chips 200 may be stacked on the semiconductor substrate 100 in a vertical direction (Z-direction). The plurality of semiconductor chips 200 may be attached to the semiconductor substrate 100 by an adhesive film or the plurality of semiconductor chips 200 and the semiconductor substrate 100 may be attached to each other by the adhesive film. The adhesive film may be formed using an adhesive film, an adhesive paste, or the like. The adhesive film may be a die attach film (DAF), but this disclosure is not limited thereto.

The plurality of semiconductor chips 200 may include connection pads electrically connected to a plurality of connection films. The connection pads may include one of copper (Cu), nickel (Ni), titanium (Ti), and aluminum (Al), or alloys thereof.

The plurality of semiconductor chips 200 may have a lower surface toward the package substrate 100 and an upper surface on which connection pads 211L to 216L and 211U to 216U are disposed. The adhesive film may be disposed on a lower surface of each of the plurality of semiconductor chips 200. The plurality of semiconductor chips 200 may be offset in the X-direction, such that each of the connection pads 211L to 216L and 211U to 216U may be exposed in the vertical direction (Z-direction). Accordingly, the plurality of semiconductor chips 200 may be stacked with steps so that the connection pads 211L to 216L and 211U to 216U are exposed.

The plurality of semiconductor chips 200 may include a non-volatile memory chip such as a flash memory, a phase-change random access memory (PRAM), a magnetoresistive random access memory (MRAM), a ferroelectric random access memory (FeRAM), or a resistive random access memory (RRAM), and/or a volatile memory chip such as a dynamic random access memory (DRAM) or a static random access memory (SRAM). The plurality of semiconductor chips 120 may include the same type of semiconductor chips, but this disclosure is not limited thereto.

The plurality of semiconductor chips 200 may include lower semiconductor chips 200L (201 and 202) and upper semiconductor chips 200U (203 and 204) electrically insulated from each other in terms of a signal path, the lower semiconductor chips 200L (201 and 202) and upper semiconductor chips 200U (203 and 204) may be driven by different channels. For example, the plurality of semiconductor chips 200 may include at least one lower semiconductor chip 200L (201 and 202) and at least one upper semiconductor chip 200U (203 and 204). The number of the lower semiconductor chips 200L (201 and 202) may be equal to the number of the upper semiconductor chips 200U (203 and 204), but this disclosure is not limited thereto. In some example implementations, the lower semiconductor chips 200L (201 and 202) and the upper semiconductor chips 200U (203 and 204) may include two semiconductor chips, respectively.

The insulator 250 may be disposed between the plurality of semiconductor chips 200. The insulator 250 may electrically insulate the plurality of semiconductor chips 200 from each other. Even when a plurality of connection interconnection lines 221L to 226L and 221U to 225U are formed according to a structure in which the plurality of semiconductor chips 200 are stacked, the plurality of semiconductor chips 200 may be electrically isolated from each other due to the disposed insulator 250. FIGS. 2A to 2B illustrate the insulator 250 as a plurality of structures spaced apart from each other, but the insulator 250 may be a structure continuously extending, in a Y-direction, on a side surface of each of the semiconductor chips 200, that is, a step region. The insulator 250 may be modified in various manners, except that the insulator 250 is disposed to not be in contact with the connection interconnection lines 221L to 226L and 221U to 225U extending from an upper portion thereof and side surfaces of the semiconductor chips 200. For example, it is illustrated that the insulator 250 covers a side surface of an upper semiconductor chip 200U and extends to front ends of pads 211L to 216L and 211U to 216U of a lower semiconductor chip 200L, but the insulator 250 may extend to have a space spaced apart from the pads 211L to 216L and 211U to 216U.

A plurality of pads 211L to 216L and 211U to 216U of the plurality of semiconductor chips 200 may include a power voltage pad connected to a power voltage, a ground voltage pad connected to a ground voltage, and a signal pad transmitting a digital signal, depending on a type of an input value. In some implementations, the plurality of pads 211L to 216L and 211U to 216U may be disposed on upper edges of the plurality of semiconductor chips 200 to be spaced apart from each other in the Y-direction. In addition, the plurality of semiconductor chips 200 may be stacked in a Z-direction, perpendicular to the upper surface of the package substrate 100 to expose the upper edges of the plurality of semiconductor chips 200. Accordingly, the plurality of pads 211L to 216L and 211U to 216U may be exposed upwardly. In each of the plurality of semiconductor chips 200, the plurality of pads 211L to 216L and 211U to 216U may be disposed in a row in the Y-direction. In each row, pads 211L to 216L and 211U to 216U disposed in the same position, among the plurality of pads 211L to 216L and 211U to 216U, may be configured to receive the same type of signal or voltage.

Accordingly, in each semiconductor chip 200, the first and fifth pads 211L, 211U, 215L, and 215U may be power voltage pads, the second and fourth pads 212L, 212U, 214L, and 214U may be signal pads, and the third and sixth pads 213L, 213U, 216L, and 216U may be ground voltage pads.

In the upper semiconductor chips 200U (203 and 204) and the lower semiconductor chips 200L (201 and 202), pads 211L to 216U, positioned in the same column, may receive the same signal or voltage. For example, the plurality of semiconductor chips 200 included in the upper semiconductor chips 200U (203 and 204) and the lower semiconductor chips 200L (201 and 202) may be the same type of semiconductor chips 200, and for example, pads 211L to 216L and 211U to 216U, complying with the same standard, may be disposed in the same position to receive the same type of input, for example, the same signals and voltage.

The plurality of connection interconnection lines 221L to 226L and 221U to 225U may electrically connect a plurality of bonding pads 111L to 116L and 111U to 116U and the plurality of pads 211L to 216L and 211U to 216U to each other, respectively. In some implementations, the plurality of connection interconnection lines 221L to 226L and 221U to 225U may be formed using an inkjet-printing method. The inkjet-printing method may include an operation of printing conductive ink on the package substrate 100 in a predetermined pattern and may print the pattern on the package substrate 100 without a patterning operation.

The plurality of connection interconnection lines 221L to 226L and 221U to 225U may include lower connection interconnection lines 221L to 226L for connecting semiconductor chips 201 and 202 of the lower semiconductor chips 200L and lower bonding pads 111L and 116L of the package substrate 100 to each other, and upper connection interconnection lines 221U to 225U for connecting semiconductor chips 203 and 204 of the upper semiconductor chips 200U (203 and 204) and upper bonding pads 111U to 116U of the package substrate 100 to each other.

Referring to FIGS. 2A to 3, the lower semiconductor chips 200L (201 and 202) may include at least one semiconductor chip, for example, two semiconductor chips 201 and 202, and the upper semiconductor chips 200U (203 and 204) may include at least one semiconductor chip, for example, two semiconductor chips 203 and 304.

The pads 211L to 216L exposed in the semiconductor chips 201 and 202 of the lower semiconductor chips 200L (201 and 202) may be disposed in a row, and may include at least six pads 211L to 216L.

The six pads 211L to 216L may be referred to as a first lower pad 211L, a second lower pad 212L, a third lower pad 213L, a fourth lower pad 214L, a fifth lower pad 215L, and a sixth lower pad 216L from the left, and may be pads 211L to 216L to which different signals or voltages are applied.

In this case, the second lower pad 212L and the fourth lower pad 214L may be pads receiving a signal, the first and fifth lower pads 211L and 215L may be pads receiving a power voltage, and the third and sixth lower pads 213L and 216L may be pads receiving a ground voltage.

The second lower pad 212L and the fourth lower pad 214L, receiving a signal, may be spaced apart from each other, and at least one voltage pad may be disposed between the second lower pad 212L and the fourth lower pad 214L, thereby physically minimizing crosstalk between the two signal pads 212L and 214L.

The first to sixth lower pads 211L to 216L of the lower semiconductor chips 200L (201 and 202) and the lower bonding pads 111L to 116L of the package substrate 100 may be disposed in a column with respect to each other. Specifically, the first to sixth lower pads 211L to 216L and the lower bonding pads 111L to 116L may be designed such that pads, disposed in the same column, receive the same signal or voltage, thereby minimizing lengths and bending of the lower connection interconnection lines 221L to 226L.

The lower connection interconnection lines 221L to 226L may include a first lower connection interconnection line 221L extending in the X-direction, the first lower connection interconnection line 221L connecting the first lower pads 211L of the lower semiconductor chips 200L (201 and 202) and the first lower bonding pad 111L to each other, a second lower connection interconnection line 222L adjacent to and spaced apart from the first lower connection interconnection line 221L in the Y-direction, the second lower connection interconnection line 222L extending in the X-direction, the second lower connection interconnection line 222L connecting the second lower pads 212L of the lower semiconductor chips 200L (201 and 202) and the second lower bonding pad 112L to each other, a third lower connection interconnection line 223L adjacent to and spaced apart from the second lower connection interconnection line 222L in the Y-direction, the third lower connection interconnection line 223L extending in the X-direction, the third lower connection interconnection line 223L connecting the third lower pads 213L of the lower semiconductor chips 200L (201 and 202) and the third lower bonding pad 113L to each other, a fourth lower connection interconnection line 224L adjacent to and spaced apart from the third lower connection interconnection line 223L in the Y-direction, the fourth lower connection interconnection line 224L extending in the X-direction, the fourth lower connection interconnection line 224L connecting the fourth lower pads 214L of the lower semiconductor chips 200L (201 and 202) and the fourth lower bonding pad 114L to each other, and a fifth lower connection interconnection line 225L adjacent to and spaced apart from the fourth lower connection interconnection line 224L in the Y-direction, the fifth lower connection interconnection line 225L extending in the X-direction, the fifth lower connection interconnection line 225L connecting the fifth lower pads 215L of the lower semiconductor chips 200L (201 and 202) and the fifth lower bonding pad 115L to each other.

The first to fifth lower connection interconnection lines 221L to 225L may be adjacent to and spaced apart from each other in the Y-direction, and may extend to be parallel to each other. The first to fifth lower connection interconnection lines 221L to 225L may not be bent in the Y-direction when extending in the X-direction.

In this case, among the lower connection interconnection lines 221L to 226L, a sixth lower connection interconnection line 226L may be a common connection interconnection line 226 simultaneously connecting the sixth pads 216U and 216L between the upper semiconductor chips 200U (203 and 204) and the lower semiconductor chips 200L (201 and 202), the common connection interconnection line extending in the X-direction. Accordingly, a ground voltage may be simultaneously applied to the sixth pads 216U and 216L between the upper semiconductor chips 200U (203 and 204) and the lower semiconductor chips 200L (201 and 202). The sixth lower connection interconnection line 226L may extend from an uppermost end to a lowermost end of the semiconductor chips 200, and may extend to the sixth lower bonding pad 116L.

The interconnection line insulating layer 240 may be disposed to cover the lower connection interconnection lines 221L to 226L.

As illustrated in FIG. 4, the interconnection line insulating layer 240 may be disposed to cover at least a portion of the upper semiconductor chips 200U (203 and 204), for example, from side surfaces of upper pads 211U to 216U of a lowermost upper semiconductor chip 203, among the upper semiconductor chips 200U (203 and 204), to the lower semiconductor chips 200L (201 and 202), and to cover the lower bonding pads 111L to 116L of the package substrate 100.

The interconnection line insulating layer 240 may cover at least a portion of an upper surface of the lowermost upper semiconductor chip 203, from side surfaces to edges of the upper pads 211U to 216U of the lowermost upper semiconductor chip 203, among the upper semiconductor chips 200U (203 and 204) and may surround side surfaces and upper surfaces of the lower connection interconnection lines 221L to 226L. In addition, the interconnection line insulating layer 240 may surround upper surfaces and side surfaces of the lower bonding pads 111L to 116L of the package substrate 100.

Accordingly, the lower connection interconnection lines 221L to 226L may not be exposed onto the interconnection line insulating layer 240, except for the sixth lower connection interconnection line 226L.

The upper connection interconnection lines 221U to 225U may be disposed on the interconnection line insulating layer 240.

The upper connection interconnection lines 221U to 225U may include a first upper connection interconnection line 221U extending in the X-direction, the first upper connection interconnection line 221U connecting first upper pads 211U of the upper semiconductor chips 200U (203 and 204) and a second upper bonding pad 112U to each other, a second upper connection interconnection line 222U adjacent to and spaced apart from the first upper connection interconnection line 221U in the Y-direction, the second upper connection interconnection line 222U extending in the X-direction, the second upper connection interconnection line 222U connecting second upper pads 212U of the upper semiconductor chips 200U (203 and 204) and a third upper bonding pad 113U to each other, a third upper connection interconnection line 223U adjacent to and spaced apart from the second upper connection interconnection line 222U in the Y-direction, the third upper connection interconnection line 223U extending in the X-direction, the third upper connection interconnection line 223U connecting third upper pads 213U of the upper semiconductor chips 200U (203 and 204) and a fourth upper bonding pad 114U to each other, a fourth upper connection interconnection line 224U adjacent to and spaced apart from the third upper connection interconnection line 223U in the Y-direction, the fourth upper connection interconnection line 224U extending in the X-direction, the fourth upper connection interconnection line 224U connecting fourth upper pads 214U of the upper semiconductor chips 200U (203 and 204) and a fifth upper bonding pad 115U to each other, and a fifth upper connection interconnection line 225U adjacent to and spaced apart from the fourth upper connection interconnection line 224U in the Y-direction, the fifth upper connection interconnection line 225U extending in the X-direction, the fifth upper connection interconnection line 225U connecting fifth upper pads 215U of the upper semiconductor chips 200U (203 and 204) and a sixth upper bonding pad 116U to each other.

The first to fifth upper connection interconnection lines 221U to 225U may be adjacent to each other and spaced apart from each other in the Y-direction, and may extend to be parallel to each other. The first to fifth upper connection interconnection lines 221U to 225U may include a first linear portion A extending in the X-direction, a bent portion B bent in the Y-direction, and a second linear portion C extending in the X-direction, the second linear portion C connected to the upper bonding pads 111U to 116U.

The bent portion B may connect the first linear portion A and the second linear portion C to each other and may be disposed on an edge of the lowermost upper semiconductor chip 203 of the upper semiconductor chips 200U (203 and 204). That is, as illustrated in FIG. 3, the bent portion B may pass through the upper pads 211U to 216U, on the lowermost upper semiconductor chip 203 of the upper semiconductor chips 200U (203 and 204) and may be bent at a predetermined angle toward the upper pads 211U to 216U adjacent thereto in an X direction, on the interconnection line insulating layer 240, at a first bent point n1. In this case, the predetermined angle may be an angle equal to or greater than 45 degrees and equal to or less than 90 degrees and may be an angle that can be extended to the second linear portion C by bending at a second bend point n2 coaxial with the adjacent upper pads 211U-216U in the X direction.

As described, the bent portions B of the upper connection interconnection lines 221U to 225U may be disposed in an edge region of the lowermost upper semiconductor chip 203, among the upper semiconductor chips 200U (203 and 204). In addition, the second bent point n2 of the previous upper connection interconnection lines 221U to 225U and the first bent point n1 of the current upper connection interconnection lines 221U to 225U may be disposed coaxially in the X-direction, and may bent at the same predetermined angle, such that the bent portions B of each of the upper connection interconnection lines 221U to 225U may be maintained in a state of being parallel to each other.

In this case, a minimum distance d1 in the X-direction between the two bending points n1 and n2 may be less than a separation distance in the X-direction between the two upper connection interconnection lines 221U to 225U.

The second linear portion C may extend from the bent portion B and the second bent point n2, and may be disposed to overlap the lower connection interconnection lines 221L to 226L, disposed therebelow in the Z-direction, in a vertical direction. The second linear portion C may be disposed with the lower connection interconnection lines 221L to 226L and the interconnection line insulating layer 240 interposed therebetween.

When the upper pads 211U to 216U of the upper semiconductor chips 200U (203 and 204) and the lower pads 211L to 216L of the lower semiconductor chips 200L (201 and 202), receiving the same type of voltage and signal, are connected to each other through different channels, the upper pads 211U to 216U of the upper semiconductor chips 200U (203 and 204) and the lower pads 211L to 216L of the lower semiconductor chips 200L (201 and 202) have the same positions, but the upper bonding pads 111U to 116U and the lower bonding pads 111L to 116L may be disposed on the package substrate 100 differently from each other. For example, the upper bonding pads 111U to 116U may be shifted one position to the right and disposed accordingly.

Due to the above arrangement, the lower connection interconnection lines 221L to 226L connecting the lower pads 211L to 216L of the lower semiconductor chips 200L (201 and 202) and the lower bonding pads 111L to 116L on the package substrate 100 to each other may be disposed to have a linear shape, and the upper connection interconnection lines 221U to 225U connecting the upper pads 211U to 216U of the upper semiconductor chips 200U (203 and 204) and the upper bonding pads 111U to 116U on the package substrate 100 to each other may be disposed to have a bent shape.

Due to the upper connection interconnection lines 221U to 225U having the bent portion B, in the upper connection interconnection lines 221U to 225U vertically overlapping the lower connection interconnection lines 221L to 226L with the interconnection line insulating layer 240 interposed therebetween, a different type of voltage or signal, from that of a voltage or signal flowing through the lower connection interconnection lines 221L to 226L, may flow.

For example, the second lower connection interconnection line 222L may be a signal interconnection line. When a high-speed digital signal is transmitted, the second upper connection interconnection line 222U, connected to the second upper pads 212U, may be bent on the lowermost upper semiconductor chip 203 and disposed to pass over the third lower connection interconnection line 223L.

The upper connection interconnection line 221U, extending onto the second lower connection interconnection line 222L, may be the first upper connection interconnection line 221U, a voltage interconnection line. Accordingly, the upper connection interconnection lines 221U to 225U may be bent and disposed, such that high-speed signal interconnection lines may not pass over or under the same type of high-speed signal interconnection lines, thereby reducing the occurrence of parasitic capacitance due to upper and lower conductive layers with the interconnection line insulating layer 240 interposed therebetween and minimizing crosstalk to improve signal quality.

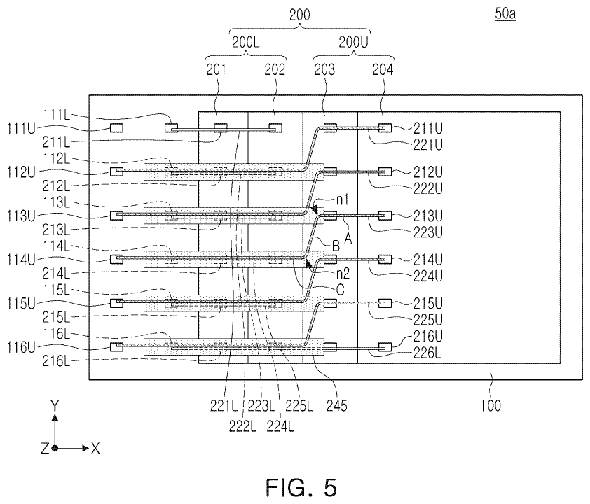

FIGS. 5 to 7 are schematic plan views of a semiconductor package according to some implementations.

A semiconductor package 50a of FIG. 5 may be the same as the semiconductor package 50 of FIGS. 2A to 4, except for a structure of an interconnection line insulating layer 240.

The interconnection line insulating layer of the semiconductor package 50a of FIG. 5 may include a plurality of interconnection line insulating patterns 245, isolated from each other.

Each of the interconnection line insulating patterns 245 may be disposed to cover lower connection interconnection lines 221L to 226L from lower pads 211L to 216L of lower semiconductor chips 200L (201 and 202) to lower bonding pads 111L to 116L.

That is, the interconnection line insulating patterns 245 may extend along the lower connection interconnection lines 221L to 226L, may have an area larger than that of the lower connection interconnection lines 221L to 226L, and may not expose the lower connection interconnection lines 221L to 226L therebelow. Each of the interconnection line insulating patterns 245 may not extend with respect to each other, but may be spaced apart from each other to insulate only the lower connection interconnection lines 221L to 226L from each other.

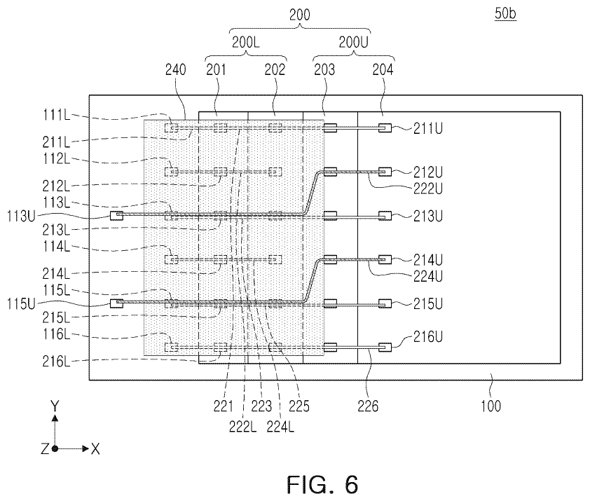

The semiconductor package 50b of FIG. 6 may be the same as the semiconductor package 50 of FIGS. 2A to 4, except that only a portion of a plurality of upper connection interconnection lines 221U to 225U is bent.

In the semiconductor package 50b of FIG. 6, six upper pads 211U to 216U and six lower pads 211L to 216L may be disposed on upper semiconductor chips 200U (203 and 204) and lower semiconductor chips 200L (201 and 202), respectively, and second upper pad 212U and third lower pad 213L (or third upper bonding pad 113U) and fourth upper pad 214U and fifth lower pad 215L (or fifth upper bonding pad 115U) may be signal pads.

In the semiconductor package 50b of FIG. 6, only a second upper connection interconnection line 222U and a fourth upper connection interconnection line 224U, connecting the signal pads to each other, may be disposed to have a bent portion B.

Specifically, first pads 211U and 211L, third pads 213U and 213L, fifth pads 215U and 215L, and sixth pads 216U and 216L may receive the same level of voltage, and accordingly the upper semiconductor chip 200U and the lower semiconductor chip 200L may include common connection interconnection lines 221, 223, 225 and 226, disposed thereon, without including connection interconnection lines physically and electrically isolated from each other.

The common connection interconnection lines 221, 223, 225, and 226 may pass from corresponding pads of the upper semiconductor chip 200U to corresponding pads of the lower semiconductor chip 200L and extend to be in contact with corresponding bonding pads 111L, 113L, 115L, and 116L on a package substrate 100. Accordingly, the common connection interconnection lines 221, 223, 225, and 226 may linearly extend in an X-direction and may be respectively in contact with the corresponding pads while running on an insulator 250 along step portions of the semiconductor chips 200.

Second lower connection interconnection line 222L and the fourth lower connection interconnection line 224L, signal interconnection lines rather than the common connection interconnection lines 221, 223, 225, and 226, may be linearly disposed to connect second and fourth lower pads 212L and 214L of the lower semiconductor chips 200L (201 and 202) and second and fourth lower bonding pads 112L and 114L of the package substrate 100 to each other.

As illustrated in FIGS. 2A and 4, the interconnection line insulating layer 240 may have a planar shape, covering all pads 211L to 216L of the lower semiconductor chips 200L (201 and 202) from front ends of upper pads 211U to 216U of the upper semiconductor chip 200U, and covering lower bonding pads 111L to 116L on the package substrate 100. Conversely, as illustrated in FIG. 5, the interconnection line insulating layer 240 may be disposed only below bent portions B and second linear portions C of the bent second and fourth upper connection interconnection lines 222U and 224U.

Among the upper connection interconnection lines 221U to 225U, second and fourth upper connection interconnection lines 222U and 224U may be signal interconnection lines, and may include a first linear portion A connected to the second and fourth upper pads 212U and 214U, a bent portion B bent on an interconnection line insulating layer 240 on a lowermost upper semiconductor chip 203, among the upper semiconductor chips 200U (203 and 204), and a second linear portion C bent from the bent portion B and disposed on the lower connection interconnection lines 212L and 214L.

Accordingly, when the signal interconnection lines 222U and 224U, among the upper connection lines 221U to 225U, pass over lower connection lines 221L to 226L, the signal interconnection lines 222U and 224U may pass over third and fifth lower connection lines 223 and 225, voltage lines rather than the second and fourth lower connection lines 222L and 224L, signal interconnection lines. As described, signal interconnection lines 222U and 224U may not be disposed above another signal interconnection line with the interconnection line insulating layer 240 between, thereby minimizing unnecessary crosstalk.

In addition, the connection interconnection lines may not be disposed on the second and fourth lower connection interconnection lines 212L and 214L, signal interconnection lines, thereby minimizing parasitic resistance caused by bending of an interconnection line.

In addition, unnecessary bonding pads on the package substrate 100 may be minimized by the common connection interconnection lines 221, 223, 225, and 226.

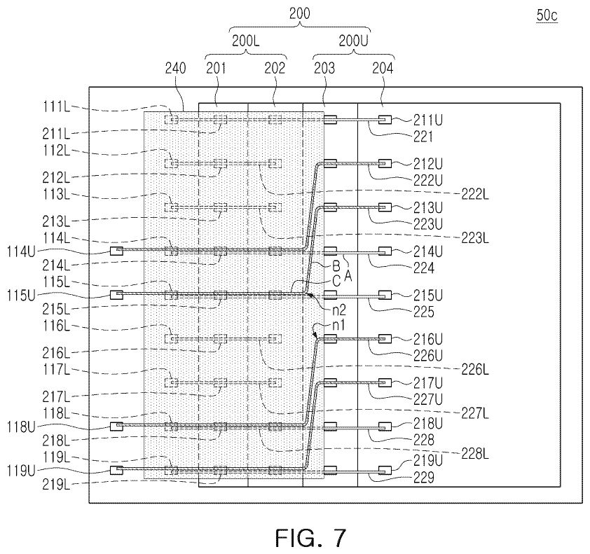

In the semiconductor package 50c of FIG. 7, nine upper pads 211U to 219U and nine lower pads 211L to 219L may be disposed on the upper semiconductor chips 200U (203 and 204) and the lower semiconductor chips 200L (201 and 202), respectively, and second upper pad 212U and third lower pad 213L, third upper pad 213U and sixth lower pad 216L, and seventh upper and lower pads 217U and 217L may be signal pads.

In the semiconductor package 50c of FIG. 7, signal pads may be consecutively disposed, and only the second and third upper connection interconnection lines 222U and 223U and the sixth and seventh upper connection interconnection lines 226U and 227U, connecting the signal pads to each other, may be disposed to have the bent portion B.

Specifically, in the first pads 211U and 211L, the fourth pads 214U and 214L, the fifth pads 215U and 215L, the eighth pads 218U and 218L, and the ninth pads 219U and 219L, pads disposed in the same column, may receive the same level of voltage, and accordingly the upper semiconductor chip 200U and the lower semiconductor chip 200L may include common connection interconnection lines 221, 224, 225, 228, and 229, disposed thereon, without including connection interconnection lines physically and electrically isolated from each other.

The common connection interconnection lines 221, 224, 225, 228, and 229 may pass from corresponding pads of the upper semiconductor chip 200U to corresponding pads of the lower semiconductor chip 200L and extend to be in contact with corresponding bonding pads 111L, 114L, 115L, 118L, and 119L on a package substrate 100. Accordingly, the common connection interconnection lines 221, 224, 225, 228, and 229 may linearly extend in an X-direction, and may be respectively in contact with the corresponding pads while running on an insulator 250 along step portions of the semiconductor chips 200.

Second, third, sixth, and seventh lower connection interconnection lines 222L, 223L, 226L, and 227L, signal interconnection lines in which the common connection interconnection lines 221, 224, 225, 228, and 229 are not disposed, may be linearly disposed to connect second, third, sixth, and seventh lower pads 212L, 213L, 216L, and 217L of the lower semiconductor chips 200L (201 and 202) and second, third, sixth, and seventh lower bonding pads 112L, 116L, and 117L of the package substrate 100 to each other.

As illustrated in FIGS. 2A and 4, the interconnection line insulating layer 240 may have a planar shape, covering all pads 211L to 219L of the lower semiconductor chips 200L (201 and 202) from front ends of upper pads 211U to 219U of the upper semiconductor chip 200U, and covering lower bonding pads 111L to 119L on the package substrate 100. Conversely, as illustrated in FIG. 5, the interconnection line insulating layer 240 may be disposed only below bent portions B and second linear portions C of the bent upper connection interconnection lines 222U, 223U, 226U and 227U.

Among the upper connection interconnection lines 221U to 229U, second upper connection interconnection line and third upper connection interconnection line 222U and 223U may be signal interconnection lines, and may include first linear portions A connected to the second and third upper pads 212U and 213U, bent portions B bent on an interconnection line insulating layer 240 on a lowermost upper semiconductor chip 203, among the upper semiconductor chips 200U (203 and 204), and second linear portions C bent from the bent portions B and disposed on lower connection interconnection lines 221L to 229L and connecting to upper bonding pads 114U and 115U.

The bent portions B may not be bent through one pad in a Y-direction but may extend to be longer than the bent portion of FIG. 6, such that the bent portions B may be bent between two pads.

The bent portion B of the second upper connection interconnection line 222U may be bent at a first bent point n1 from the second upper pad 212U, may extend in the Y-direction on the interconnection line insulating layer 240 of the lowermost upper semiconductor chip 203, and may have a second bent point n2 bent again in front of the fourth upper pad 214U.

Accordingly, the second bent point n2, a contact point between the bent portion B and the second linear portion C, may be disposed coaxially with the fourth upper pad 214U. As described, the bent portion B may be disposed to be longer, such that the second upper connection interconnection line 222U may extend onto a fourth lower connection interconnection line 224L rather than a third lower connection interconnection line (common connection interconnection line) 223 adjacent thereto.

As described, when signal interconnection lines are consecutively disposed, the bent portion B may be formed to be longer so as not to extend onto a signal interconnection line adjacent thereto, thereby minimizing unnecessary crosstalk.

In this case, the adjacent third upper connection interconnection line 223U may also have a bent portion B formed to pass through two pads, and the bent portions B of the upper connection interconnection lines 222U and 223U may have the same length and may be disposed to be parallel to each other.

Accordingly, when signal interconnection lines, among the upper connection interconnection lines 221U to 225U, pass over the lower connection interconnection lines 221L to 226L, the signal interconnection lines may pass over the lower connection interconnection lines 221L to 226L, voltage interconnection lines, rather than the lower connection interconnection lines 221L to 226L, signal interconnection lines. As described, the signal interconnection lines may not be disposed above and below each other with the interconnection line insulating layer 240 between, thereby minimizing unnecessary crosstalk.

In addition, a connection interconnection line may not be disposed on the second and third lower connection interconnection lines 212L and 213L, signal interconnection lines, among the lower connection interconnection lines 211L to 219L, thereby minimizing parasitic resistance caused by bending of an interconnection line.

Among the upper connection interconnection lines 221U to 229U, sixth upper connection interconnection line and the seventh upper connection interconnection lines 226U and 227U may also be signal interconnection lines, and may include a first linear portion A connected to the sixth and seventh upper pads 216U and 217U, a bent portion B bent on the interconnection line insulating layer 240 on the lowermost upper semiconductor chip 203, among the upper semiconductor chips 200U (203 and 204), and a second linear portion C bent from the bent portion B and disposed on the lower connection interconnection line 211L to 219L.

The bent portion B may extend long enough to pass through two pads in the Y-direction. The sixth upper connection interconnection line and the seventh upper connection interconnection lines 226U and 227U may also have a longer bent portion B, such that the sixth and seventh upper connection interconnection lines 226U and 227U may extend onto eighth and ninth lower connection interconnection lines 228L and 229L rather than seventh and eighth lower connection interconnection lines 227L and 228L adjacent thereto. The sixth and seventh upper connection interconnection lines 226U and 227U may contact the eighth and ninth upper bonding pads 118U and 119U.

As described, when signal interconnection lines are consecutively disposed, the bent portion B may be formed to be longer so as not to extend onto a signal interconnection line adjacent thereto, such that signal interconnection lines may not be vertically disposed, thereby minimizing unnecessary crosstalk.

In this case, the bent portions B of the adjacent sixth and seventh upper connection interconnection lines 226U and 227U may have the same length, may be disposed to be parallel to each other, may have a length, the same as that of the bent portions B of the second and third upper connection interconnection lines 222U and 223U, and may be disposed to be parallel to the bent portions B of the second and third upper connection interconnection lines 222U and 223U.

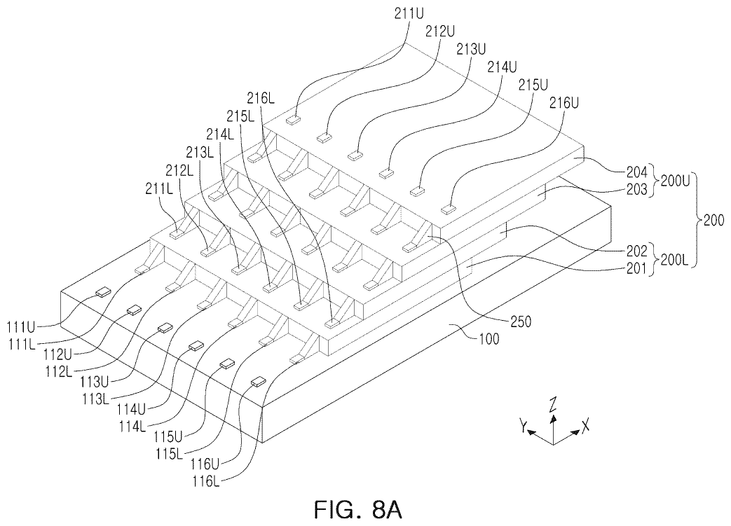

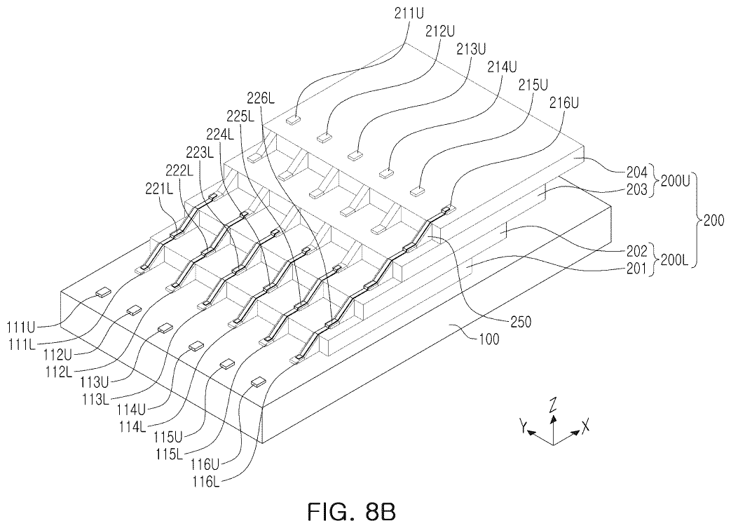

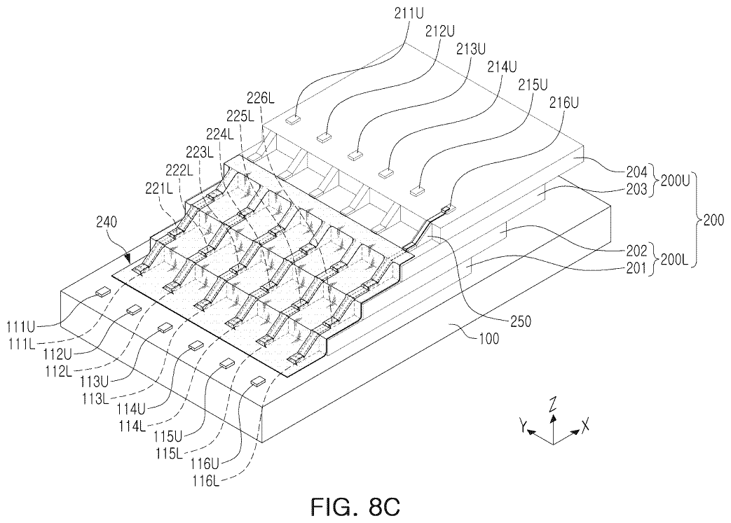

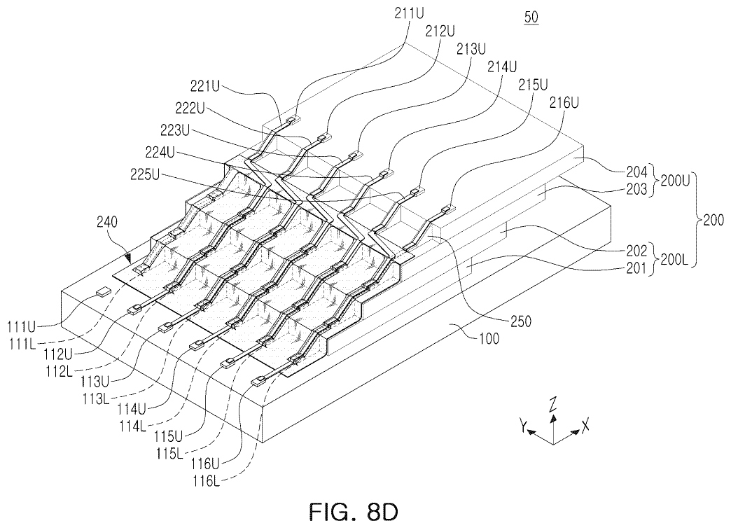

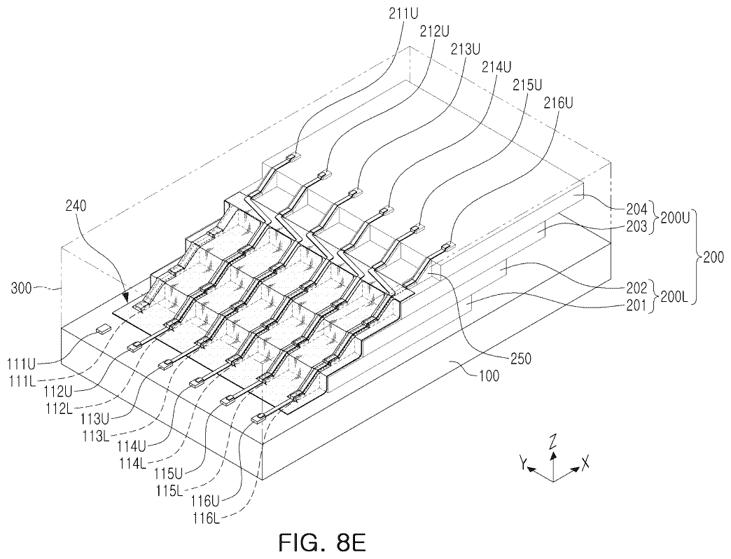

FIGS. 8A to 8E are perspective views of a method of manufacturing a semiconductor package 50 according to some implementations.

Referring to FIG. 8A, a plurality of semiconductor chips 200 may be stacked on a package substrate 100. The package substrate 100 may be a strip substrate including a plurality of unit substrates. The plurality of semiconductor chips 200 may be stacked on unit substrates. The plurality of semiconductor chips 200 may be attached to each other by adhesive films. The plurality of semiconductor chips 200 may be disposed such that pads 211L to 216L and 211U to 215U are adjacent to bonding pads 111L to 116L and 111U to 116U of the package substrate 100. The plurality of semiconductor chips 200 may be shifted in one direction (for example, an X-direction), such that the pads 211L to 216L and 211U to 215U may be exposed in a vertical direction (Z-direction), respectively.

Referring to FIG. 8B, an insulator 250 may be formed in a step region of the semiconductor chips 200 stacked on each other. The insulator 250 may be selectively formed in a specific region by scanning a molding layer or printing but may be formed to expose the pads 211L to 216L and 211U to 215U to the entire step region.

Lower connection interconnection lines 221L to 226L may be formed on the insulator 250 and the pads 211L to 216L and 211U to 215U.

The lower connection interconnection lines 221L to 226L may be formed by plating a conductive material to connect pads 211L to 216L of lower semiconductor chips 200L (201 and 202) and lower bonding pads 111L to 116L on a package substrate 100 to each other in an X-direction using inkjet-printing or patterning, or may be formed using a dispensing process, but this disclosure is not limited thereto. The lower connection interconnection lines 221L to 226L may be formed by attaching an anisotropic conductive film. A plurality of lower connection interconnection lines 221L to 226L may extend from above the pads 211L to 216L, between the lower semiconductor chips 200L (201 and 202), and may extend onto exposed surfaces of a semiconductor chip 200L and the insulator 250, thereby continuously extending to the corresponding pads 211L to 216L of the semiconductor chip 200L therebelow.

Referring to FIG. 8C, an interconnection line insulating layer 240 may be formed on the lower connection interconnection lines 221L to 226L. The interconnection line insulating layer 240 may be formed by curing a molding material to entirely cover the lower connection interconnection lines 221L to 226L, the lower pads 211L to 216L, and the lower bonding pads 111L to 116L, but this disclosure is not limited thereto.

Except for a common connection interconnection line 226L, all of the lower connection interconnection lines 221L to 226L and the lower pads 211L to 216L may not be externally exposed by the interconnection line insulating layer 240.

Referring to FIG. 8D, upper connection interconnection lines 221U to 225U may be formed on the interconnection line insulating layer 240.

The upper connection interconnection lines 221U to 225U may be formed by plating a conductive material or a dispensing process to include a first linear portion A, a bent portion B, and a second linear portion C connecting upper pads 211U to 215U of an upper semiconductor chips 200U (203 and 204) and upper bonding pads 111U to 116U on the package substrate 100 to each other in the X-direction using inkjet-printing or patterning. The lower connection interconnection lines 221L to 226L may be formed by attaching an anisotropic conductive film. A plurality of upper connection interconnection lines 221U to 225U may extend from above the pads 211U to 215U, between the upper semiconductor chips 200U (203 and 204), and may extend onto the exposed surfaces of a semiconductor chip 200U and the insulator 250, thereby extending from the bent portion B and the second linear portion C to upper bonding pads 111U to 116U of the package substrate 100 therebelow.

Referring to FIG. 8E, a molding material may flow on the package substrate 100. The molding material may be formed to cover the plurality of semiconductor chips 200 using a transfer process or a compression process. The molding material may be formed to cover the plurality of upper connection interconnection lines 221U to 225U.

A mold 300 may be formed by curing a molding material (for example, an EMC) covering the plurality of semiconductor chips 200. A planarization process may be applied to an upper portion of the mold 300. According to some implementations, the mold 300 may be ground to be thinner and a thinned semiconductor package 50 may be implemented. Thereafter, individual packages may be isolated from each other by forming a connection bump and performing a sawing process.

According to example implementations, a semiconductor package may include a first chip group and a second chip group connected through different signal interconnection lines, and upper second signal lines may be bent and disposed, such that first signal interconnection lines connected to the first chip group and the second signal interconnection lines connected to the second chip group may not vertically overlap each other.

Accordingly, the first and second signal interconnection lines to signals are transmitted at a similar speed may be disposed to vertically overlap power interconnection lines with an insulating layer interposed therebetween, thereby reducing the effect of crosstalk caused by mutual inductance and/or capacitance between the signal interconnection lines, and improving signal quality.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations have been shown and described above, it will be apparent to those skilled in the art that modifications and variations could be made without departing from the scope as defined by the appended claims.

What is claimed is:

1. A semiconductor package comprising:
a package substrate including a plurality of bonding pads, the plurality of bonding pads comprising first bonding pads and second bonding pads;
a lower semiconductor chip group on an upper surface of the package substrate, the lower semiconductor chip group including at least one lower semiconductor chip comprising lower pads arranged to connect to different types of inputs;
an upper semiconductor chip group on the lower semiconductor chip group, the upper semiconductor chip group including at least one upper semiconductor chip comprising upper pads arranged to connect to different types of inputs;
first connection interconnection lines connecting the first bonding pads and the lower pads to each other, respectively; and
second connection interconnection lines connecting the second bonding pads and the upper pads to each other, respectively, wherein the second connection interconnection lines are extend over the first connection interconnection lines and are spaced apart from one another,
wherein each second connection interconnection line includes
a first linear portion connected to a respective one of the upper pads,
a second linear portion offset from the first linear portion, the second linear portion connected to a respective one of the second bonding pads, and
a bent portion connecting the first linear portion and the second linear portion to each other.

2. The semiconductor package of claim 1, wherein the at least one lower semiconductor chip and the at least one upper semiconductor chip are stacked in a stepwise manner in a first direction that is perpendicular to the upper surface of the package substrate.

3. The semiconductor package of claim 2, wherein the at least one lower semiconductor chip and the at least one upper semiconductor chip include the same type of semiconductor chip.

4. The semiconductor package of claim 3, wherein
the lower pads of the at least one lower semiconductor chip are spaced apart from each other in a second direction within a row, wherein the second direction is parallel to the upper surface of the substrate,
wherein the upper pads of the at least one upper semiconductor chip are spaced apart from each other in the second direction within a second row, wherein each upper pad is aligned with a respective lower pad to provide a respective column, and
wherein the lower pads and the upper pads in each column are connected to the same type of input.

5. The semiconductor package of claim 4, wherein
the lower pads include first voltage pads, wherein each first voltage pad is configured to receive a power voltage or a ground voltage as a first voltage pad input voltage, and
the lower pads include first signal pads, wherein each first signal pad is configured to receive a first signal for the lower semiconductor chip group as a first signal pad input signal, and
the upper pads include second voltage pads, wherein each second voltage pad is configured to receive the power voltage or the ground voltage as a second voltage pad input voltage, and
the upper pads include second signal pads, wherein each second signal pad is configured to receive a second signal for the upper semiconductor chip group as a second voltage pad input signal.

6. The semiconductor package of claim 5, wherein the first connection interconnection lines continuously extend in a third direction that is perpendicular to the first direction, and connect either the first voltage pads or the first signal pads to the first bonding pads.

7. The semiconductor package of claim 5, wherein each second connection interconnection line is configured to transmit a different type of input from a respective first connection interconnection lines that overlaps the second linear portion of the second connection interconnection line.

8. The semiconductor package of claim 5, wherein a subset of the second connection interconnection lines are connected to the second signal pads and overlap, in the first direction, a subset of the first connection interconnection lines that are connected to the first voltage pads.

9. The semiconductor package of claim 5, comprising:
a common connection interconnection line connecting a first voltage pad to a second voltage pad in a same column as the first voltage pad.

10. The semiconductor package of claim 5, wherein
the first voltage pads and the second voltage pads are connected to each other by common connection interconnection lines, respectively,
the first signal pads are connected, respectively, to the second signal pads by a respective first connection interconnection line and a respective second connection interconnection line, wherein the respective first connection interconnection line and the respective second connection interconnection line are spaced apart from each other.

11. The semiconductor package of claim 10, comprising:
an interconnection line insulating structure, wherein the interconnection line insulating structure electrically insulates the first connection interconnection lines and the second connection interconnection lines from each other.

12. The semiconductor package of claim 11, wherein the interconnection line insulating structure includes an interconnection line insulating layer exposing the upper pads of a lowermost upper semiconductor chip of the upper semiconductor chip group, and
wherein the interconnection line insulating layer covers the lower pads of the lower semiconductor chip group and the first connection interconnection lines.

13. The semiconductor package of claim 11, wherein the interconnection line insulating structure includes a plurality of interconnection line insulating patterns exposing the upper pads of a lowermost upper semiconductor chip of the upper semiconductor chip group,
wherein the plurality of interconnection line insulating patterns cover the lower pads of the lower semiconductor chip group and the first connection interconnection lines, and
wherein the plurality of interconnection line insulating patterns are spaced apart from each other.

14. The semiconductor package of claim 11, wherein, for each second connection interconnection line, the bent portion and the second linear portion are on the interconnection line insulating structure.

15. A semiconductor package comprising:
a package substrate including a plurality of bonding pads, wherein the plurality of bonding pads comprise first bonding pads and second bonding pads;
a lower semiconductor chip group on an upper surface of the package substrate, wherein the lower semiconductor chip group includes at least one lower semiconductor chip including lower pads arranged to connect to different types of inputs;
an upper semiconductor chip group on the lower semiconductor chip group, wherein the upper semiconductor chip group includes at least one upper semiconductor chip including upper pads arranged to connect to different types of inputs;
first connection interconnection lines connecting the first bonding pads to the lower pads, respectively; and
second connection interconnection lines connecting the second bonding pads to the upper pads, respectively, wherein the second connection interconnection lines extend over the first connection interconnection lines and are spaced apart from one other,
wherein, for each second connection interconnection line, at least a portion overlaps a respective one of the first connection interconnection lines in a vertical direction,
wherein each second connection interconnection line is arranged to connect to a different input than the respective first connection interconnection lines that the second connection interconnection line extends over.

16. The semiconductor package of claim 15, wherein
the lower pads comprise first voltage pads configured to receive a power voltage or a ground voltage as a first voltage pad input,
wherein the lower pads comprise first signal pads configured to receive first signals for the lower semiconductor chip group as first signal pad inputs,
wherein the upper pads comprise second voltage pads configured to receive the power voltage or the ground voltage as a second voltage pad input,
wherein the upper pads comprise second signal pads configured to receive second signals for the upper semiconductor chip group as second signal pad inputs,
wherein the first bonding pads and the lower pads are arranged in a plurality of column, and
wherein the second bonding pads are offset from the upper pads.

17. The semiconductor package of claim 16, wherein each of the second connection interconnection lines extends in a first direction that is perpendicular to the vertical direction to be in contact with a respective one of the upper pads of the at least one upper semiconductor chip, and is bent to be in contact with a respective one of the second bonding pads offset from the upper pad.

18. The semiconductor package of claim 15, comprising
an interconnection line insulating structure on the first connection interconnection lines, wherein the interconnection line insulating structure electrically insulates the first connection interconnection lines and the second connection interconnection lines from each other.

19. The semiconductor package of claim 15, wherein the first and second connection interconnection lines include electrically conductive ink.

20. A semiconductor package comprising:
a package substrate including a plurality of bonding pads;
a lower semiconductor chip group on an upper surface of the package substrate, wherein the lower semiconductor chip group includes at least one lower semiconductor chip including first signal pads connected to first signal inputs;
an upper semiconductor chip group on the lower semiconductor chip group, wherein the upper semiconductor chip group includes at least one upper semiconductor chip including second signal pads connected to second signal inputs;
first connection interconnection lines electrically connecting the bonding pads and the first signal pads to each other, respectively; and
second connection interconnection lines electrically connecting the bonding pads and the second signal pads to each other to each other, respectively,
wherein the second connection interconnection lines are offset from the first connection interconnection lines in a vertical direction.
